(19) United States
(12) Patent Application Publication
(10) Pub. No.: US 2022/0390559 A1
(43) Pub. Date: Dec. 8, 2022

(54) FUSED CAMERA AND LIDAR SYSTEM

(71) Applicant: GM Cruise Holdings LLC, San Francisco, CA (US)

(72) Inventor: Shane McGuire, Redwood City, CA (US)

(21) Appl. No.: 17/341,345

(22) Filed: Jun. 7, 2021

(51) Int. Cl. G01S 7/481; G01S 17/931; G01S 17/89; H01L 27/146; H01L 31/107; B60W 30/00

(52) U.S. Cl. CPC G01S 7/481; G01S 17/931; G01S 17/89; H01L 27/14643; H01L 31/107; B60W 30/00

(57) ABSTRACT

Various technologies described herein pertain to a fused camera and lidar system for an autonomous vehicle. The fused camera and lidar system includes a fused receiver. The fused receiver includes optics configured to receive a received electromagnetic signal from an environment nearby the fused camera and lidar system. The fused receiver further includes a beam splitter configured to split the received electromagnetic signal into a first split electromagnetic signal (including wavelengths in a visible spectrum) and a second split electromagnetic signal (including wavelengths in an infrared spectrum). The fused receiver also includes a camera pipeline and a lidar pipeline. The camera pipeline can generate image data based on the first split electromagnetic signal, and the lidar pipeline can generate lidar data based on the second split electromagnetic signal.

### BACKGROUND

An autonomous vehicle is a motorized vehicle that can operate without human conduction. An exemplary autonomous vehicle includes a plurality of sensor systems, such as but not limited to, a lidar sensor system, a camera sensor system, and a radar sensor system, amongst others. The autonomous vehicle operates based upon sensor signals output by the sensor systems.

The differing types of sensor systems included in an autonomous vehicle can enhance overall performance of the autonomous vehicle. For instance, a first type of sensor system may be better suited than a second type of sensor system to detect a first type of object or event in an environment nearby the autonomous vehicle, whereas the second type of sensor system may be better suited than the first type of sensor system to detect a second type of object or event in the environment nearby the autonomous vehicle. Moreover, the differing types of sensor systems can provide redundancy for the autonomous vehicle.

While conventional autonomous vehicles oftentimes include different types of sensor systems, the different sensor systems are typically separate within the autonomous vehicle. The separate sensor systems can occupy a significant amount of space within the autonomous vehicle and add to the overall system cost.

### SUMMARY

The following is a brief summary of subject matter that is described in greater detail herein. This summary is not intended to be limiting as to the scope of the claims.

Described herein are various technologies that pertain to a fused camera and lidar system for an autonomous vehicle. The fused camera and lidar system can include a fused receiver. The fused receiver can include optics configured to receive a received electromagnetic signal from an environment nearby the fused camera and lidar system (e.g., nearby the autonomous vehicle that includes the fused camera and lidar system). The fused receiver can further include a beam splitter configured to split the received electromagnetic signal into a first split electromagnetic signal and a second split electromagnetic signal. The first split electromagnetic signal can include wavelengths in a visible spectrum and the second split electromagnetic signal can include wavelengths in an infrared spectrum. The beam splitter, for example, can include a dichroic coated mirror. Moreover, the fused receiver can include a camera pipeline and a lidar pipeline. The first split electromagnetic signal can be inputted to the camera pipeline. The camera pipeline can be configured to generate image data based on the first split electromagnetic signal. Further, the second split electromagnetic signal can be inputted to the lidar pipeline. The lidar pipeline can be configured to generate lidar data based on the second split electromagnetic signal. The fused camera and lidar system can further include a lidar transmitter configured to transmit a transmitted electromagnetic signal into the environment nearby the fused camera and lidar system. A portion of the received electromagnetic signal received by the optics of the fused receiver can correspond to the transmitted electromagnetic signal.

According to various embodiments, the camera pipeline can include a camera detector and the lidar pipeline can include a lidar detector. The camera detector can include a complementary metal-oxide-semiconductor (CMOS) image sensor. Moreover, the lidar detector can include a single-photon avalanche diode (SPAD) array. The first split electromagnetic signal can be directed to illuminate the camera detector. Further, the second split electromagnetic signal can be directed to illuminate the lidar detector.

According to various embodiments, the fused camera and lidar system can include a shared processing system. The shared processing system can be configured to process the image data and the lidar data generated. Moreover, according to other embodiments, it is contemplated that the fused camera and lidar system can include a first processing system configured to process the image data and a separate, second processing system configured to process the lidar data.

Pursuant to various embodiments, the fused receiver can include a frontend device. The frontend device can include the optics, the beam splitter, a waveguide, a first output port, and a second output port. The waveguide can be between the optics and the beam splitter. Moreover, the first output port can be configured to output the first split electromagnetic signal, and the second output port can be configured to output the second split electromagnetic signal. Thus, according to such embodiments, the optics, the beam splitter, the waveguide, the first output port, and the second output port can be integrated as part of a single device.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

FIG. 1 illustrates a functional block diagram of an exemplary fused camera and lidar system for an autonomous vehicle.

FIG. 2 illustrates functional block diagram of an exemplary fused receiver of the fused camera and lidar system of FIG. 1.

FIG. 3 illustrates functional block diagram of another exemplary fused receiver of the fused camera and lidar system of FIG. 1.

FIG. 4 illustrates functional block diagram of a further exemplary fused receiver of the fused camera and lidar system of FIG. 1.

FIG. 5 illustrates a functional block diagram of an exemplary autonomous vehicle that includes the fused camera and lidar system.

FIG. 6 illustrates an exemplary computing device.

### DETAILED DESCRIPTION

Various technologies pertaining to a fused camera and lidar system for an autonomous vehicle are now described with reference to the drawings, wherein like reference numerals are used to refer to like elements throughout. In the following description, for purposes of explanation, numerous specific details are set forth in order to provide a thorough understanding of one or more aspects. It may be evident, however, that such aspect(s) may be practiced without these specific details. In other instances, well-known structures and devices are shown in block diagram form in order to facilitate describing one or more aspects. Further, it is to be understood that functionality that is described as being carried out by certain system components may be performed by multiple components. Similarly, for instance, a component may be configured to perform functionality that is described as being carried out by multiple components.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

As used herein, the terms “component” and “system” are intended to encompass computer-readable data storage that is configured with computer-executable instructions that cause certain functionality to be performed when executed by a processor. The computer-executable instructions may include a routine, a function, or the like. It is also to be understood that a component or system may be localized on a single device or distributed across several devices. Further, as used herein, the term “exemplary” is intended to mean “serving as an illustration or example of something.”

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

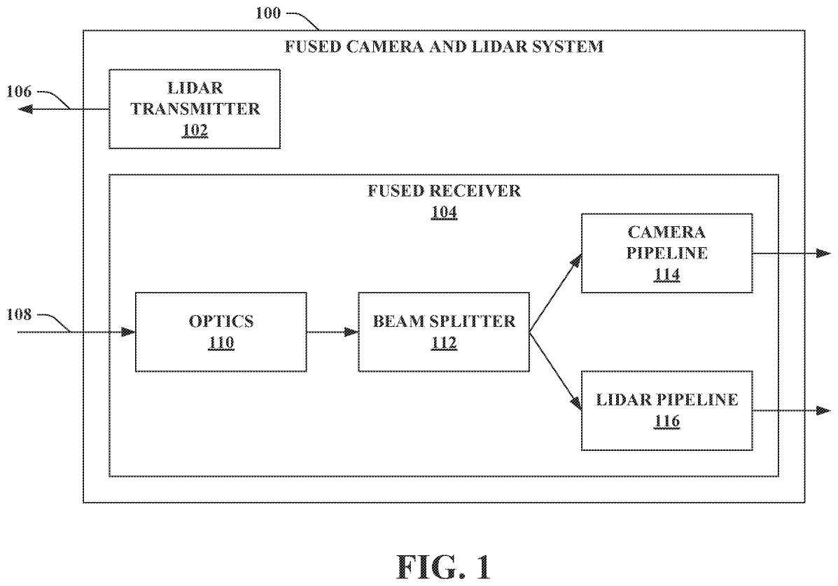

Referring now to the drawings, FIG. 1 illustrates an exemplary fused camera and lidar system 100 for an autonomous vehicle. The fused camera and lidar system 100 includes a lidar transmitter 102 and a fused receiver 104. The lidar transmitter 102 can be configured to transmit a transmitted electromagnetic signal 106 into an environment nearby the fused camera and lidar system 100. The transmitted electromagnetic signal 106 can include electromagnetic radiation having wavelengths in an infrared spectrum. Moreover, the fused receiver 104 can be configured to receive a received electromagnetic signal 108 from the environment nearby the fused camera and lidar system 100. A portion of the received electromagnetic signal 108 received by the fused receiver 104 can correspond to the transmitted electromagnetic signal 106. For instance, at least a portion of the transmitted electromagnetic signal 106 transmitted by the lidar transmitter 102 can reflect off an object in the environment and return to the fused camera and lidar system 100. The received electromagnetic signal 108 can include electromagnetic radiation having wavelengths in both a visible spectrum and the infrared spectrum.

The fused receiver 108 can include optics 110, a beam splitter 112, a camera pipeline 114, and a lidar pipeline 116. The optics 110 can be configured to receive the received electromagnetic signal 108 from the environment nearby the fused camera and lidar system 104. The optics 110 can include a single lens assembly that receives the received electromagnetic signal 108. Thus, the single lens assembly can be used to receive electromagnetic radiation having wavelengths in both the visible spectrum and the infrared spectrum.

Moreover, the beam splitter 112 can be configured to split the received electromagnetic signal 108 into a first split electromagnetic signal and a second split electromagnetic signal. The first split electromagnetic signal can include wavelengths in a visible spectrum (e.g., 400 to 700 nanometers). Further, the second split electromagnetic signal can include wavelengths in an infrared spectrum (e.g., 700 nanometers to 1 millimeter, 850 to 940 nanometers, etc.). The beam splitter 112, for example, can include a dichroic coated mirror. Following this example, the dichroic coated mirror can allow a portion of the received electromagnetic signal with wavelengths above a threshold wavelength to pass there through, while a differing portion of the received electromagnetic signal with wavelengths below the threshold wavelength can be reflected by the dichroic coated mirror. Thus, the dichroic coated mirror can split the received electromagnetic signal 108 based on the wavelength of the electromagnetic radiation with minimal transmission loss.

The first split electromagnetic signal can be inputted to the camera pipeline 114. The camera pipeline 114 can be configured to generate image data based on the first split electromagnetic signal (including the wavelengths in the visible spectrum). The camera pipeline 114, for instance, can include a camera detector. Accordingly, the first split electromagnetic signal can be directed to illuminate the camera detector. Moreover, the camera pipeline 114 can generate the image data based on the first split electromagnetic signal that illuminates the camera detector.

The second split electromagnetic signal can be inputted to the lidar pipeline 116. The lidar pipeline 116 can be configured to generate lidar data based on the second split electromagnetic signal (including the wavelengths in the infrared spectrum). For example, the lidar pipeline 116 can include a lidar detector. Accordingly, the second split electromagnetic signal can be directed to illuminate the lidar detector. The lidar pipeline 116 can generate the lidar data based on the second split electromagnetic signal that illuminates the lidar detector.

Although not depicted, it is contemplated that the lidar transmitter 102 can include various components. For instance, the lidar transmitter 102 can include a laser, a modulator, a resonator, frontend optics, and the like. The laser, for example, can be a semiconductor laser, a laser diode, or the like. Moreover, the lidar transmitter 102 and the lidar pipeline 116 (as well as the optics 110 and the beam splitter 112) can provide a time of flight (TOF) lidar system, a frequency modulated continuous wavelength (FMCW) lidar system, or the like as part of the fused camera and lidar system 100.

The fused camera and lidar system 100 can integrate a camera sensor system and a lidar sensor system into a single unit. Accordingly, the fused camera and lidar system 100 can include fewer parts as compared to conventional approaches that include a separate camera sensor system and lidar sensor system, since common receive optics 110 can be used in the fused camera and lidar system 100. The beam splitter 112 can enable directing electromagnetic radiation having the appropriate wavelengths to the camera pipeline 114 and the lidar pipeline 116.

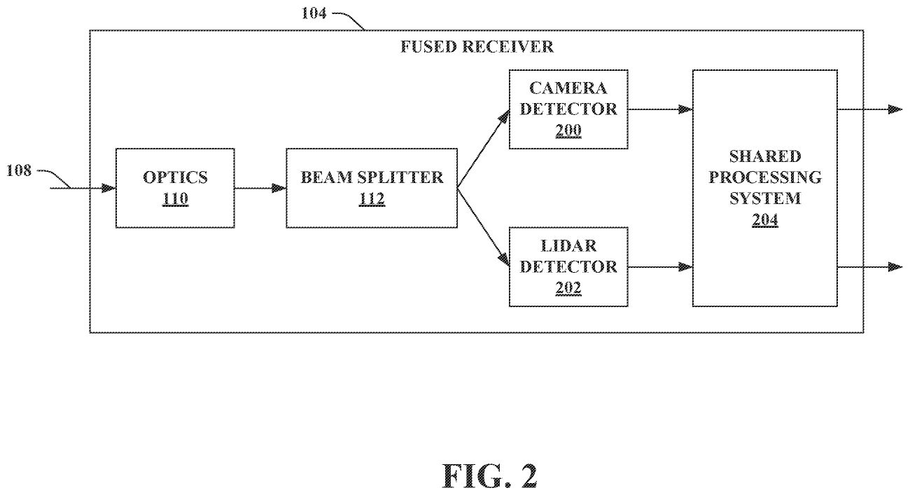

Now turning to FIG. 2, illustrated is the fused receiver 104 according to various embodiments. As noted above, the fused receiver 104 includes the optics 110, the beam splitter 112, the camera pipeline 114, and the lidar pipeline 116. As depicted in FIG. 2, the camera pipeline 114 can include a camera detector 200, and the lidar pipeline 116 can include a lidar detector 202. Moreover, in the example set forth in FIG. 2, the fused receiver 104 includes a shared processing system 204.

Again, the optics 110 are configured to receive the received electromagnetic signal from the environment nearby the fused receiver 104. Moreover, the beam splitter 112 can be configured to split the received electromagnetic signal into the first split electromagnetic signal and the second split electromagnetic signal. The first split electromagnetic signal, which comprises wavelengths in the visible spectrum, can be directed to illuminate the camera detector 200. Moreover, the second split electromagnetic signal, which includes wavelengths in the infrared spectrum, can be directed to illuminate the lidar detector 202. According to an example, the camera detector 200 can include a complementary metal-oxide-semiconductor (CMOS) image sensor. The lidar detector 202, for example, can include a single-photon avalanche diode (SPAD) array. However, the claimed subject matter is not limited to the foregoing examples.

In the example of FIG. 2, the shared processing system 204 can be configured to process the image data and the lidar data. The camera detector 200 can output a stream of raw digital image data that can be inputted to the shared processing system 204. Moreover, the lidar detector 202 can output a stream of raw digital lidar data that can be inputted to the shared processing system 204. The raw data streams from the camera detector 200 and the lidar detector 202 can be inputted to a single processing system, namely, the shared processing system 204. Accordingly, the shared processing system 204 can process both raw data streams. For instance, the shared processing system 204 can convert the raw digital image data from the camera detector 200 and the raw digital lidar data from the lidar detector 202 to a format that can be sent over a network (e.g., ethernet). Pursuant to an illustration, the data outputted by the shared processing system 204 can be sent over a network to a computing system of an autonomous vehicle.

According to various examples, the shared processing system 204 can include an application-specific integrated circuit (ASIC) configured to process both raw data streams from the camera detector 200 and the lidar detector 202. In accordance with another example, the shared processing system 204 can include a field programmable gate array (FPGA) configured to process both raw data streams from the camera detector 200 and the lidar detector 202.

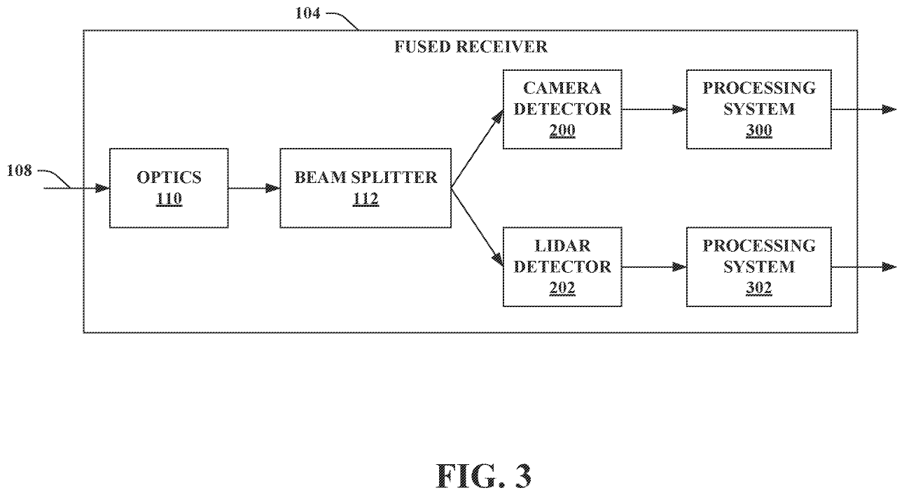

With reference to FIG. 3, illustrated is another exemplary embodiment of the fused receiver 104. The fused receiver 104, as described above, includes the optics 110, the beam splitter 112, the camera pipeline 114, and the lidar pipeline 116. Similar to FIG. 2, the camera pipeline 114 can include the camera detector 200, and the lidar pipeline 116 can include the lidar detector 202.

In the embodiment shown in FIG. 3, the fused receiver 104 includes a first processing system 300 and a second processing system 302 (as opposed to the shared processing system 204 of FIG. 2). The first processing system 300 can be configured to process the image data, and the second processing system 302 can be configured to process the lidar data. Thus, the fused receiver 104 of FIG. 3 can include separate processing systems for processing the raw data streams outputted by the camera detector 200 and the lidar detector 202. More particularly, the first processing system 300 can process the stream of raw digital image data outputted by the camera detector 200, and the second processing system 302 can process the stream of raw digital lidar data outputted by the lidar detector 202.

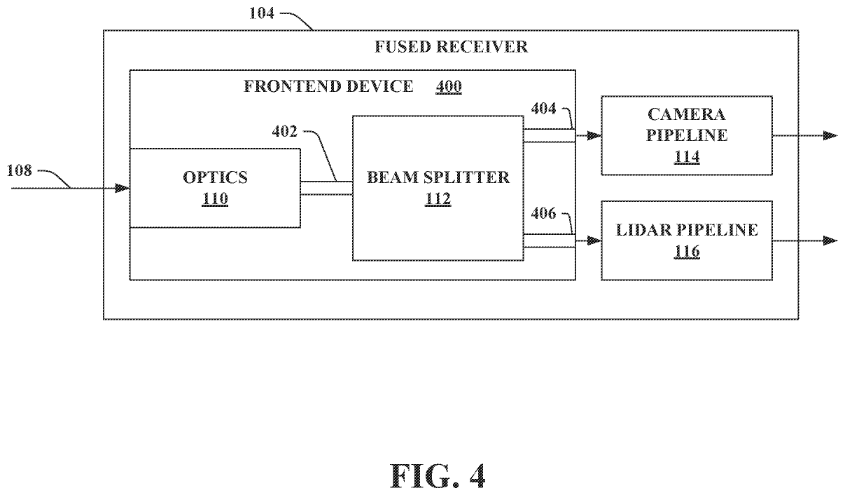

Turning to FIG. 4, illustrated is another exemplary embodiment of the fused receiver 104. In the example of FIG. 4, the fused receiver 104 includes a frontend device 400, the camera pipeline 114, and the lidar pipeline 116. The frontend device 400 includes the optics 110 and the beam splitter 112. The frontend device 400 further includes a waveguide 402 between the optics 110 and the beam splitter 112. Moreover, the frontend device 400 includes a first output port 404 and a second output port 406. The first output port 404 is configured to output the first split electromagnetic signal that includes wavelengths in the visible spectrum; thus, the first split electromagnetic signal outputted via the first output port 404 can be provided to the camera pipeline 114. The second output port 406 is configured to output the second split electromagnetic signal that includes wavelengths in the infrared spectrum; the second split electromagnetic signal outputted via the second output port 406 can be provided to the lidar pipeline 116. Moreover, it is contemplated that the frontend device 400 can include a waveguide between the beam splitter 112 and the first output port 404 and another waveguide between the beam splitter 112 and the second output port 406.

As opposed to being discrete elements, the optics 110, the waveguide 402, the beam splitter 112, the first output port 404, and the second output port 406 can be integrated into a single device, namely, the frontend device 400, in the embodiment shown in FIG. 4. Accordingly, the frontend device 400 can be configured to receive the received electromagnetic signal 108 from the environment nearby the fused receiver 104 (e.g., nearby the fused camera and lidar system 100, nearby an autonomous vehicle that includes such system). The frontend device 400 can further output the first split electromagnetic signal via the first output port 404 to the camera pipeline and the second split electromagnetic signal via the second output port 406 to the lidar pipeline 116.

Reference is now generally made to FIGS. 1-4. It is contemplated that the electromagnetic signals described herein can travel between elements of the fused receiver 104 via waveguides, through free space, a combination thereof, and so forth.

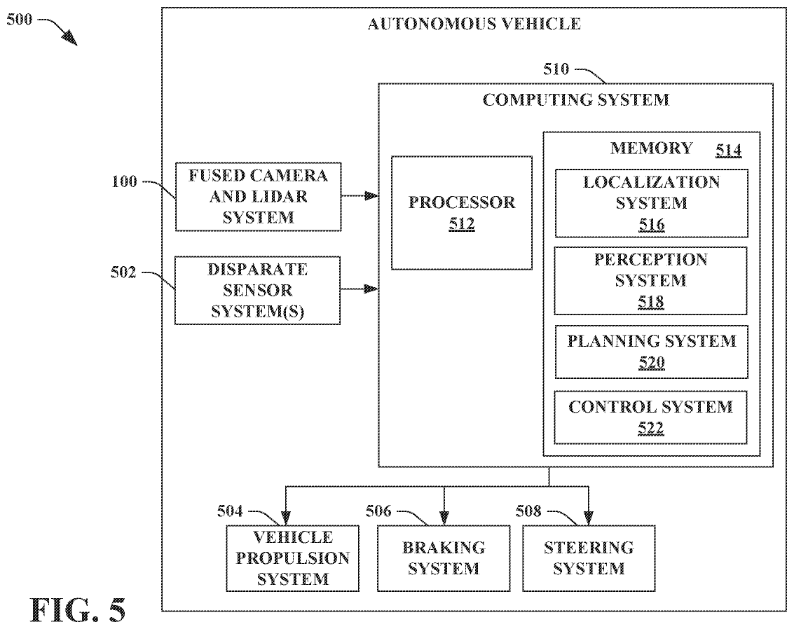

Turning to FIG. 5, illustrates an autonomous vehicle 500. The autonomous vehicle 500 can navigate about roadways without human conduction based upon sensor signals outputted by sensor systems of the autonomous vehicle 500. The autonomous vehicle 500 includes a plurality of sensor systems. More particularly, the autonomous vehicle 500 includes the fused camera and lidar system 100. The autonomous vehicle 500 can further include one or more disparate sensor systems 502. The disparate sensor systems 502 can include radar sensor systems, GPS sensor systems, ultrasonic sensor sensors, infrared sensor systems, a camera system (separate from the fused camera and lidar system 100), a lidar sensor system (separate from the fused camera and lidar 100), and the like. The sensor systems 100 and 502 can be arranged about the autonomous vehicle 500.

The autonomous vehicle 500 further includes several mechanical systems that are used to effectuate appropriate motion of the autonomous vehicle 500. For instance, the mechanical systems can include, but are not limited to, a vehicle propulsion system 504, a braking system 506, and a steering system 508. The vehicle propulsion system 504 may be an electric engine or a combustion engine. The braking system 506 can include an engine brake, brake pads, actuators, and/or any other suitable componentry that is configured to assist in decelerating the autonomous vehicle 500. The steering system 508 includes suitable componentry that is configured to control the direction of movement of the autonomous vehicle 500.

The autonomous vehicle 500 additionally includes a computing system 510 that is in communication with the sensor systems 100 and 502, the vehicle propulsion system 504, the braking system 506, and the steering system 508. The computing system 510 includes a processor 512 and memory 514; the memory 514 includes computer-executable instructions that are executed by the processor 512. Pursuant to various examples, the processor 512 can be or include a graphics processing unit (GPU), a plurality of GPUs, a central processing unit (CPU), a plurality of CPUs, an application-specific integrated circuit (ASIC), a microcontroller, a programmable logic controller (PLC), a field programmable gate array (FPGA), or the like.

The memory 514 of the computing system 510 can include a localization system 516, a perception system 518, a planning system 520, and a control system 522. The localization system 516 can be configured to determine a local position of the autonomous vehicle 500. The perception system 518 can be configured to perceive objects nearby the autonomous vehicle 500 (e.g., based on outputs from the sensor systems 100 and 502). For instance, the perception system 518 can detect, classify, and predict behaviors of objects nearby the autonomous vehicle 500. The perception system 518 (and/or differing system(s) included in the memory 514) can track the objects nearby the autonomous vehicle 500 and/or make predictions with respect to the environment in which the autonomous vehicle 500 is operating (e.g., predict the behaviors of the objects nearby the autonomous vehicle 500). Further, the planning system 522 can plan motion of the autonomous vehicle 500. Moreover, the control system 522 can be configured to control at least one of the mechanical systems of the autonomous vehicle 500 (e.g., at least one of the vehicle propulsion system 504, the braking system 506, and/or the steering system 508).

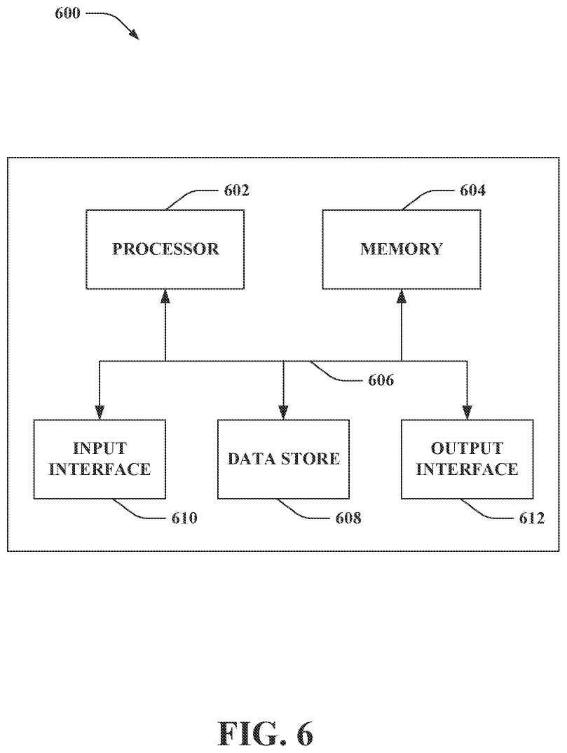

Referring now to FIG. 6, a high-level illustration of an exemplary computing device 600 that can be used in accordance with the systems and methodologies disclosed herein is illustrated. For instance, the computing device 600 may be or include the computing system 510. The computing device 600 includes at least one processor 602 that executes instructions that are stored in a memory 604. The instructions may be, for instance, instructions for implementing functionality described as being carried out by one or more systems discussed above or instructions for implementing one or more of the methods described above. The processor 602 may be a GPU, a plurality of GPUs, a CPU, a plurality of CPUs, a multi-core processor, etc. The processor 602 may access the memory 604 by way of a system bus 606. In addition to storing executable instructions, the memory 604 may also store various data.

The computing device 600 additionally includes a data store 608 that is accessible by the processor 602 by way of the system bus 606. The data store 608 may include executable instructions, various data, etc. The computing device 600 also includes an input interface 610 that allows external devices to communicate with the computing device 600. For instance, the input interface 610 may be used to receive instructions from an external computer device, etc. The computing device 600 also includes an output interface 612 that interfaces the computing device 600 with one or more external devices. For example, the computing device 600 may transmit control signals to the vehicle propulsion system 504, the braking system 506, and/or the steering system 508 by way of the output interface 612.

Additionally, while illustrated as a single system, it is to be understood that the computing device 600 may be a distributed system. Thus, for instance, several devices may be in communication by way of a network connection and may collectively perform tasks described as being performed by the computing device 600.

Various functions described herein can be implemented in hardware, software, or any combination thereof. If implemented in software, the functions can be stored on or transmitted over as one or more instructions or code on a computer-readable medium. Computer-readable media includes computer-readable storage media. A computer-readable storage media can be any available storage media that can be accessed by a computer. By way of example, and not limitation, such computer-readable storage media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer. Disk and disc, as used herein, include compact disc (CD), laser disc, optical disc, digital versatile disc (DVD), floppy disk, and blu-ray disc (BD), where disks usually reproduce data magnetically and discs usually reproduce data optically with lasers. Further, a propagated signal is not included within the scope of computer-readable storage media. Computer-readable media also includes communication media including any medium that facilitates transfer of a computer program from one place to another. A connection, for instance, can be a communication medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio and microwave are included in the definition of communication medium. Combinations of the above should also be included within the scope of computer-readable media.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the scope of the appended claims. Furthermore, to the extent that the term “includes” is used in either the details description or the claims, such term is intended to be inclusive in a manner similar to the term “comprising” as “comprising” is interpreted when employed as a transitional word in a claim.

What is claimed is:

1. A fused camera and lidar system, comprising:
a fused receiver, comprising:
optics configured to receive a received electromagnetic signal from an environment nearby the fused camera and lidar system;
a beam splitter configured to split the received electromagnetic signal into a first split electromagnetic signal and a second split electromagnetic signal, wherein the first split electromagnetic signal comprises wavelengths in a visible spectrum and the second split electromagnetic signal comprises wavelengths in an infrared spectrum;
a camera pipeline, the first split electromagnetic signal being inputted to the camera pipeline, the camera pipeline being configured to generate image data based on the first split electromagnetic signal; and
a lidar pipeline, the second split electromagnetic signal being inputted to the lidar pipeline, the lidar pipeline being configured to generate lidar data based on the second split electromagnetic signal.

2. The fused camera and lidar system of claim 1, further comprising:
a lidar transmitter configured to transmit a transmitted electromagnetic signal into the environment nearby the fused camera and lidar system, wherein a portion of the received electromagnetic signal corresponds to the transmitted electromagnetic signal.

3. The fused camera and lidar system of claim 1, wherein:
the camera pipeline comprises a camera detector, the first split electromagnetic signal being directed to illuminate the camera detector; and
the lidar pipeline comprises a lidar detector, the second split electromagnetic signal being directed to illuminate the lidar detector.

4. The fused camera and lidar system of claim 3, the camera detector comprises a complementary metal-oxide-semiconductor (CMOS) image sensor.

5. The fused camera and lidar system of claim 3, the lidar detector comprises a single-photon avalanche diode (SPAD) array.

6. The fused camera and lidar system of claim 1, further comprising:
a shared processing system, the shared processing system configured to process the image data and the lidar data.

7. The fused camera and lidar system of claim 1, further comprising:
a first processing system configured to process the image data; and
a second processing system configured to process the lidar data.

8. The fused camera and lidar system of claim 1, the beam splitter comprises a dichroic coated mirror.

9. The fused camera and lidar system of claim 1, the fused receiver comprises a frontend device, the frontend device comprises:
the optics;
the beam splitter;
a waveguide between the optics and the beam splitter;
a first output port configured to output the first split electromagnetic signal; and
a second output port configured to output the second split electromagnetic signal.

10. The fused camera and lidar system of claim 1, wherein an autonomous vehicle comprises the fused camera and lidar system.

11. A fused receiver of a camera and lidar system, comprising:
optics configured to receive a received electromagnetic signal from an environment nearby the fused receiver;
a beam splitter configured to split the received electromagnetic signal into a first split electromagnetic signal and a second split electromagnetic signal, wherein the first split electromagnetic signal comprises wavelengths in a visible spectrum and the second split electromagnetic signal comprises wavelengths in an infrared spectrum;
a camera pipeline, the first split electromagnetic signal being inputted to the camera pipeline, the camera pipeline being configured to generate image data based on the first split electromagnetic signal; and
a lidar pipeline, the second split electromagnetic signal being inputted to the lidar pipeline, the lidar pipeline being configured to generate lidar data based on the second split electromagnetic signal.

12. The fused receiver of claim 11, wherein:
the camera pipeline comprises a camera detector, the first split electromagnetic signal being directed to illuminate the camera detector; and
the lidar pipeline comprises a lidar detector, the second split electromagnetic signal being directed to illuminate the lidar detector.

13. The fused receiver of claim 12, wherein:
the camera detector comprises a complementary metal-oxide-semiconductor (CMOS) image sensor; and
the lidar detector comprises a single-photon avalanche diode (SPAD) array.

14. The fused receiver of claim 11, further comprising:
a shared processing system, the shared processing system configured to process the image data and the lidar data.

15. The fused receiver of claim 11, the beam splitter comprises a dichroic coated mirror.

16. The fused receiver of claim 11, comprising:
a frontend device, comprising:
the optics;
the beam splitter;
a waveguide between the optics and the beam splitter;
a first output port configured to output the first split electromagnetic signal; and
a second output port configured to output the second split electromagnetic signal.

17. An autonomous vehicle, comprising:
a fused camera and lidar system, comprising:
a lidar transmitter configured to transmit a transmitted electromagnetic signal into an environment nearby the autonomous vehicle; and
a fused receiver, comprising:
optics configured to receive a received electromagnetic signal from the environment nearby the autonomous vehicle, wherein a portion of the received electromagnetic signal corresponds to the transmitted electromagnetic signal;
a beam splitter configured to split the received electromagnetic signal into a first split electromagnetic signal and a second split electromagnetic signal, wherein the first split electromagnetic signal comprises wavelengths in a visible spectrum and the second split electromagnetic signal comprises wavelengths in an infrared spectrum;
a camera pipeline, the first split electromagnetic signal being inputted to the camera pipeline, the camera pipeline being configured to generate image data based on the first split electromagnetic signal; and
a lidar pipeline, the second split electromagnetic signal being inputted to the lidar pipeline, the lidar pipeline being configured to generate lidar data based on the second split electromagnetic signal.

18. The autonomous vehicle of claim 17, wherein:
the camera pipeline comprises a camera detector, the first split electromagnetic signal being directed to illuminate the camera detector; and
the lidar pipeline comprises a lidar detector, the second split electromagnetic signal being directed to illuminate the lidar detector.

19. The autonomous vehicle of claim 17, the fused receiver further comprising:
a shared processing system, the shared processing system configured to process the image data and the lidar data.

20. The autonomous vehicle of claim 17, the beam splitter comprises a dichroic coated mirror.
